(19) United States
(12) Patent Application Publication
(10) Pub. No.: US 2025/0118718 A1
(43) Pub. Date: Apr. 10, 2025

(54) SEMICONDUCTOR DEVICE AND MANUFACTURING METHOD THEREOF

(71) Applicant: SK hynix Inc., Gyeonggi-do (KR)

(72) Inventor: Heon Yong CHANG, Gyeonggi-do (KR)

(21) Appl. No.: 18/440,975

(22) Filed: Feb. 14, 2024

(30) Foreign Application Priority Data
Oct. 5, 2023 (KR) 10-2023-0132318

(51) Int. Cl. H01L 25/18; H01L 21/78; H01L 23/00; H01L 23/29; H01L 23/31; H01L 23/58; H01L 25/00; H10B 80/00

(52) U.S. Cl. CPC H01L 25/18; H01L 21/78; H01L 23/3185; H01L 23/3192; H01L 24/05; H01L 24/08; H01L 24/20; H01L 24/80; H01L 24/94; H01L 25/50; H10B 80/00; H01L 23/291; H01L 23/585; H01L 24/19; H01L 2224/05624; H01L 2224/05647; H01L 2224/05657; H01L 2224/05684; H01L 2224/08145; H01L 2224/19; H01L 2224/221; H01L 2224/80357; H01L 2224/80379; H01L 2224/80896; H01L 2224/8093; H01L 2224/94; H01L 2924/05442; H01L 2924/1436; H01L 2924/1437; H01L 2924/1438; H01L 2924/1441; H01L 2924/1443

(57) ABSTRACT

A semiconductor device includes a first chip having a first chip body and a first bonding layer which is disposed on the first chip body and includes a first bonding pad; and a second chip bonded on the first bonding layer, and having a second chip body and a second bonding layer which is disposed under the second chip body and includes a second bonding pad bonded to the first bonding pad, wherein a side surface of the first bonding layer and a side surface of the second chip are retracted inward of a side surface of the first chip body.

### CROSS-REFERENCE TO RELATED APPLICATION

The present application claims priority under 35 U.S.C. § 119 (a) to Korean Patent Application No. 10-2023-0132318 filed in the Korean Intellectual Property Office on Oct. 5, 2023, which is incorporated herein by reference in its entirety.

### BACKGROUND

### 1. Technical Field

Various embodiments generally relate to a semiconductor device and a manufacturing method thereof.

### 2. Related Art

A technology of forming a semiconductor device by bonding wafers using a hybrid bonding process and then dicing the bonded wafers has been proposed. The reliability of the semiconductor device to which the hybrid bonding process is applied may degrade due to delamination of bonded surfaces.

### SUMMARY

Various embodiments of the disclosed technology are directed to a semiconductor device with improved reliability and a method for manufacturing the same.

In an embodiment, a semiconductor device may include: a first chip including a first chip body and a first bonding layer disposed on the first chip body, the first bonding layer including a first bonding pad; and a second chip bonded on the first bonding layer, the second chip including a second chip body and a second bonding layer disposed under the second chip body, wherein the second bonding layer includes a second bonding pad bonded to the first bonding pad, wherein a side surface of the first bonding layer and a side surface of the second chip are retracted inward of a side surface of the first chip body.

In an embodiment, a semiconductor device may include: a first chip including a first chip body including a device region in which a peripheral circuit is defined and a scribe lane region which surrounds the device region, and a first bonding layer disposed on the first chip body and including a first bonding pad; and a second chip bonded on the first bonding layer, and including a second bonding layer including a second bonding pad which is bonded to the first bonding pad and a second chip body disposed on the second bonding layer and including a memory cell array, wherein the first bonding layer and the second chip overlap with the device region of the first chip body, and do not overlap with the scribe lane region of the first chip body.

In an embodiment, a method for manufacturing a semiconductor device may include: providing first and second wafers including a device region and a scribe lane region surrounding the device region; forming, in each of the first and second wafers, a bonding layer and a chip body disposed on the bonding layer, the bonding layer including a bonding pad which is disposed in the device region and a dummy bonding pad which is disposed in the scribe lane region; bonding a first bonding layer of the first wafer and a second bonding layer of the second wafer; forming a trench by removing a second chip of the second wafer and the first bonding layer of the scribe lane region; forming an insulating member which fills the trench; and cutting the scribe lane region.

According to the embodiments of the disclosed technology, it is possible to suppress or/and prevent bonded semiconductor chips from delaminating, thereby improving the reliability of a semiconductor device.

### BRIEF DESCRIPTION OF THE DRAWINGS

FIG. 1 is a schematic cross-sectional view of a semiconductor device based on an embodiment of the disclosed technology.

FIG. 2 is a detailed view of a part A of FIG. 1.

FIGS. 3 to 12 are views for explaining a method for manufacturing a semiconductor device based on an embodiment of the disclosed technology.

FIG. 13 is a schematic cross-sectional view of a semiconductor device based on an embodiment of the disclosed technology.

FIG. 14 is a detailed view of a part B of FIG. 13.

FIG. 15 is a schematic cross-sectional view of a semiconductor device based on an embodiment of the disclosed technology.

### DETAILED DESCRIPTION

Hereinafter, embodiments of the present disclosure will be described in detail with reference to the accompanying drawings. In the following description, the same elements will be designated by the same reference numerals although they are shown in different drawings. Further, in the following description of the present disclosure, a detailed description of known functions and configurations incorporated herein will be omitted when it may make the subject matter of the present disclosure rather unclear. It is to be noticed that the terms “comprising,” “having,” “including” and so on, used in the description and claims, should not be interpreted as being restricted to the means listed thereafter unless specifically stated otherwise. Where an indefinite or definite article is used when referring to a singular noun, e.g., “a,” “an” and “the,” this may include a plural of that noun unless specifically stated otherwise.

Also, in describing the components of the disclosure, there may be terms used like first, second, A, B, (a), and (b). These are solely for the purpose of differentiating one component from another component but do not limit the substances, order, sequence or number of the components.

In descriptions for the positional relationships of components, in the case where it is described that at least two components are “connected,” “coupled” or “linked,” it is to be understood that the at least two components may be directly “connected,” “coupled” or “linked” but may be indirectly “connected,” “coupled” or “linked” with another component interposed between the two components. Here, another component may be included in at least one of the at least two components which are “connected,” “coupled” or “linked” with each other.

In descriptions for time flow relationships of components, an operating method or a fabricating method, in the case where pre and post relationships in terms of time or pre and post relationships in terms of flow are described, for example, by “after,” “following,” “next” or “before,” non-continuous cases may be included unless “immediately” or “directly” is used.

In the case where a numerical value for a component or its corresponding information (e.g., level, etc.) is mentioned, even though there is no separate explicit description, the numerical value or its corresponding information can be interpreted as including an error range that may be caused by various factors (for example, a process variable, an internal or external shock, noise, etc.).

Hereinafter, various embodiments of the disclosed technology will be described in detail with reference to the accompanying drawings.

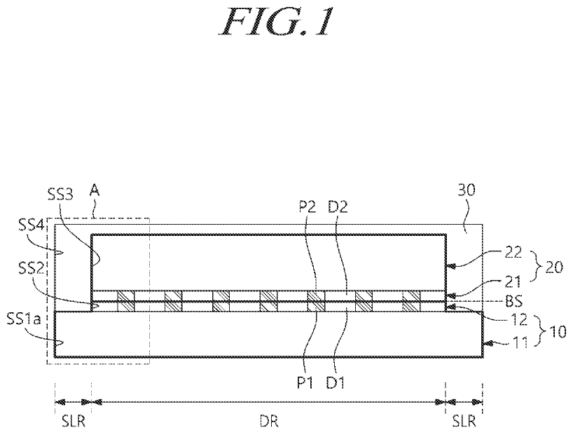

FIG. 1 is a schematic cross-sectional view of a semiconductor device according to an embodiment of the disclosed technology.

Referring to FIG. 1, the semiconductor device according to an embodiment of the disclosed technology may include a device region DR and a scribe lane region SLR around the device region DR. The scribe lane region SLR may surround the device region DR.

The semiconductor device according to an embodiment of the disclosed technology may include a first chip 10, a second chip 20, and an insulating member 30.

The first chip 10 and the second chip 20 may be fabricated on different wafers and may then be bonded to each other by a bonding process, such as, for example, a hybrid bonding process. Hybrid bonding is also known in this art as direct bonding (or direct bond interconnection “DBI”) or fusion bonding and typically involves creating metal-to-metal connections created between the semiconductor chips that are bonded together without the need for additional intermediate layers (such as solder or adhesive).

The first chip 10 may include a first chip body 11 and a first bonding layer 12 which is disposed on the first chip body 11.

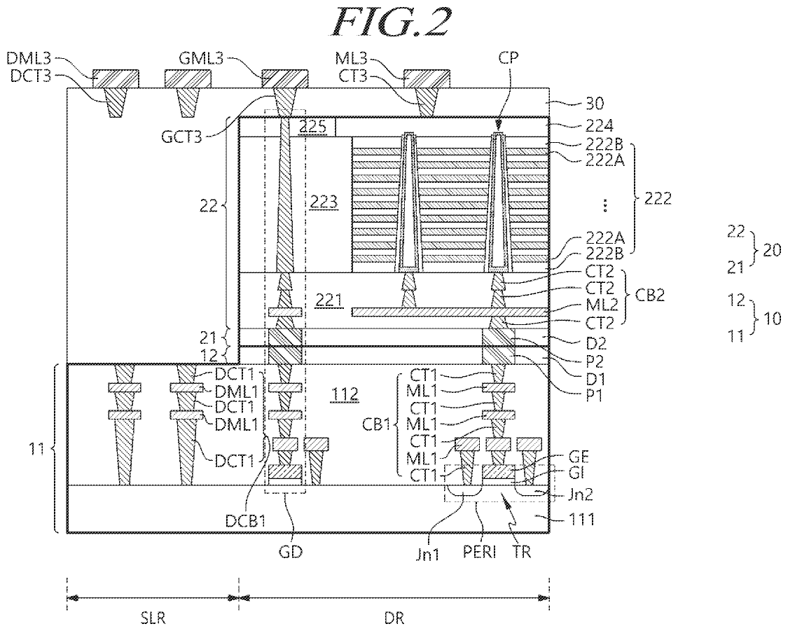

As will be described later with reference to FIG. 2, the first chip body 11 may include a substrate, a peripheral circuit, and an interconnection structure which is electrically connected to the peripheral circuit.

The first bonding layer 12 may include a plurality of first bonding pads P1 and a first bonding insulating layer D1 which electrically isolates the first bonding pads P1. The first bonding pad P1 may be connected to the interconnection structure, and may be connected to the peripheral circuit through the interconnection structure.

The first bonding pads P1 may include, for example, copper (Cu) which has high electrical conductivity and excellent electro-migration characteristics, but is not limited thereto. The first bonding pads P1 may include a metal material, for example, at least one of copper (Cu), tungsten (W), cobalt (Co), aluminum (Al), silicide and any combination thereof. The first bonding insulating layer D1 may include, for example, silicon oxide (SiO₂). The first bonding layer 12 may have a top surface which is planarized by a chemical mechanical polishing (CMP) process.

The second chip 20 may include a second bonding layer 21 and a second chip body 22 which is disposed on the second bonding layer 21.

The second bonding layer 21 may include a plurality of second bonding pads P2 and a second bonding insulating layer D2 which electrically isolates the second bonding pads P2.

The second bonding pads P2 may include a metal material, for example, at least one of copper (Cu), tungsten (W), cobalt (Co), aluminum (Al), silicide and any combination thereof. The second bonding insulating layer D2 may include, for example, silicon oxide (SiO₂). The second bonding layer 21 may have a bottom surface which is planarized by a chemical mechanical polishing (CMP) process.

As will be described later with reference to FIG. 2, the second chip body 22 may include a memory cell array and an interconnection structure. The memory cell array may be connected to the interconnection structure, and may be connected to the second bonding pads P2 through the interconnection structure.

The top surface of the first bonding layer 12 and the bottom surface of the second bonding layer 21 may be bonded by a hybrid bonding process. As the first bonding pads P1 and the second bonding pads P2 are bonded to each other, metal-metal junctions may be formed. As the first bonding insulating layer D1 and the second bonding insulating layer D2 are bonded to each other, dielectric-dielectric junctions may be formed.

As a result of the hybrid bonding process, a bonding interface BS may be formed between the first bonding layer 12 and the second bonding layer 21. The bonding interface BS may be a place where the first bonding layer 12 and the second bonding layer 21 are bonded to each other. In an embodiment, the bonding interface BS may be a layer of a specific thickness including the top surface of the first bonding layer 12 and the bottom surface of the second bonding layer 21.

A side surface SS2 of the first bonding layer 12 and a side surface SS3 of the second chip 20 may be retracted inward of a side surface SS1a of the first chip body 11. The edge portion of the first chip body 11 may protrude beyond the side surface SS2 of the first bonding layer 12 and the side surface SS3 of the second chip 20.

The first bonding layer 12 and the second chip 20 may be disposed on the device region DR of the first chip body 11. The first bonding layer 12 and the second chip 20 may overlap with the device region DR of the first chip body 11, and may not overlap with the scribe lane region SLR of the first chip body 11. The scribe lane region SLR of the first chip body 11 may protrude beyond the side surface SS2 of the first bonding layer 12 and the side surface SS3 of the second chip 20.

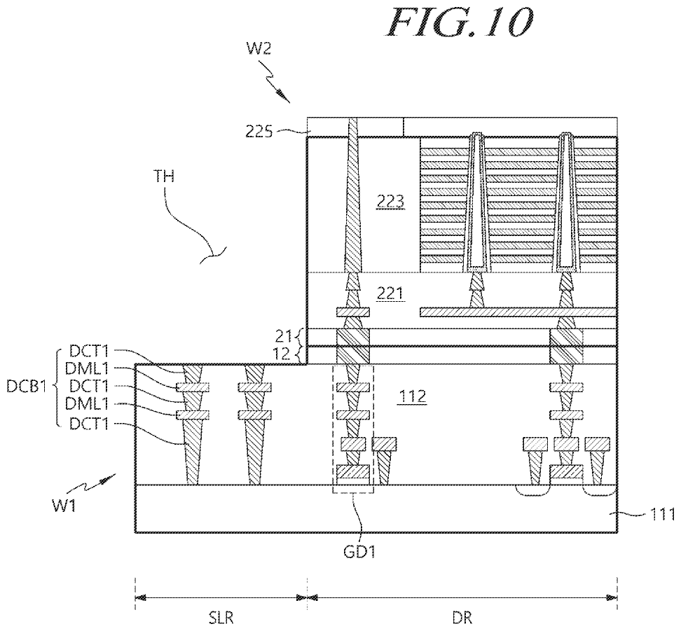

The side surface SS2 of the first bonding layer 12 and the side surface SS3 of the second chip 20 may be disposed on a single surface. As will be described later with reference to FIG. 10, the scribe lane region SLR of a second wafer (W2 of FIG. 10) and the scribe lane region SLR of the first bonding layer 12 may be removed by an etching process. The side surface SS2 of the first bonding layer 12 and the side surface SS3 of the second chip 20 which are created by the etching process may be disposed on the same surface.

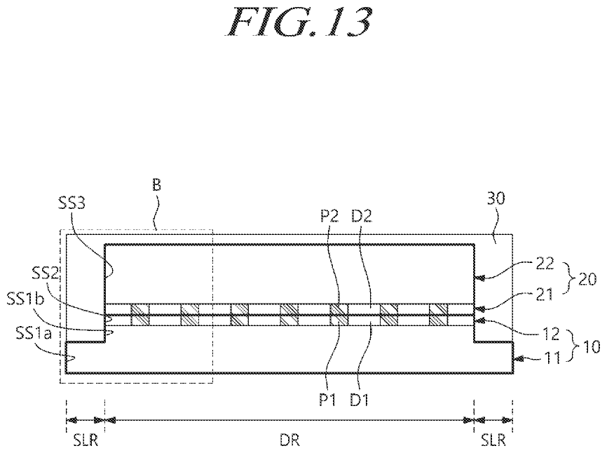

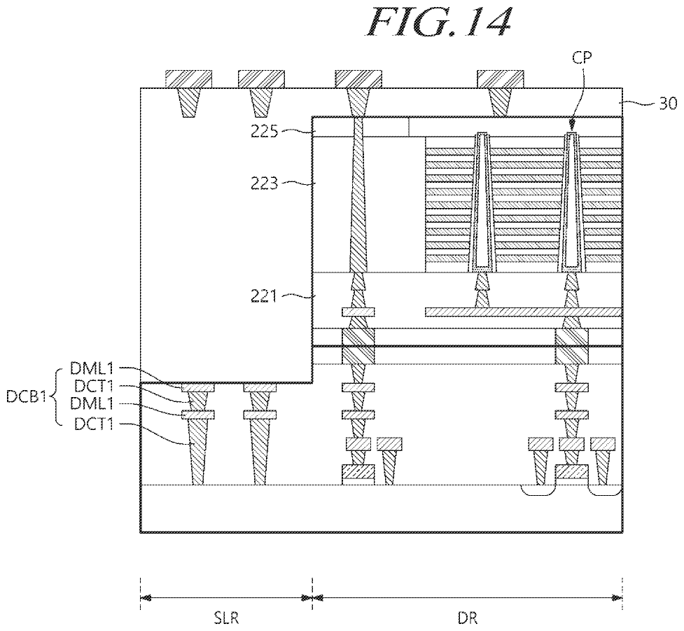

The top surface of the scribe lane region SLR of the first chip body 11 may be positioned at the same level as the top surface of the device region DR of the first chip body 11. However, the disclosed technology is not limited thereto. For example, as will be described later with reference to FIGS. 13 and 14, the top surface of the scribe lane region SLR of the first chip body 11 may be positioned to be lower than the top surface of the device region DR of the first chip body 11.

The insulating member 30 may be defined on the scribe lane region SLR of the first chip body 11 and the second chip 20 to cover the side surface SS2 of the first bonding layer 12 and the side surface SS3 and the top surface of the second chip 20. The insulating member 30 may have a top surface which is planarized by a CMP process.

The insulating member 30 may be formed by an insulating material with a modulus of rupture smaller than that of the first and second bonding pads P1 and P2. The insulating member 30 may include at least one of oxide, nitride, SiCOH, N-doped SiC (NDC) and any combination thereof.

A side surface SS4 of the insulating member 30 and the side surface SS1a of the first chip body 11 may be disposed on the same surface. As will be described later, after forming the insulating member 30, the insulating member 30 and the first chip body 11 of the scribe lane region SLR may be cut through a dicing process. The side surface SS4 of the insulating member 30 and the side surface SS1a of the first chip body 11 which are created by the dicing process may be disposed on the same surface.

FIG. 2 is a detailed view of a part A of FIG. 1.

Referring to FIG. 2, the semiconductor device may be a memory device. The first chip 10 may include a peripheral circuit PERI which controls the operation of the memory cell array, and the second chip 20 may include the memory cell array.

Hereinafter, a case where the semiconductor device is a NAND flash memory will be described, but the disclosed technology is not limited thereto. The semiconductor device may include a nonvolatile memory such as a resistive RAM (RRAM), a phase-change RAM (PRAM), a magnetoresistive RAM (MRAM) and a ferroelectric RAM (FRAM) or a volatile memory such as a dynamic random access memory (DRAM) and a static RAM (SRAM).

The first chip body 11 may include a substrate 111, the peripheral circuit PERI, a first insulating layer 112, a first interconnection structure CB1 and a first dummy interconnection structure DCB1.

The substrate 111 may include silicon (e.g., monocrystalline silicon), silicon (SiGe), gallium arsenide (GaAs), germanium (Ge), silicon-on-insulator (SOI), or any other suitable material.

The peripheral circuit PERI may be disposed on the device region DR of the substrate 111. The peripheral circuit PERI may include a transistor TR. The transistor TR may include impurity regions Jn1 and Jn2, a gate insulating layer GI and a gate electrode GE. The impurity regions Jn1 and Jn2 may be formed by doping impurities into the substrate 111. The channel region of the transistor TR may be formed between the impurity regions Jn1 and Jn2, and the gate insulating layer GI may be disposed on the channel region. The gate electrode GE may be disposed on the gate insulating layer GI. The peripheral circuit PERI may further include, in addition to the transistor TR, any active or passive component, for example, at least one of a diode, a resistor and a capacitor.

The first insulating layer 112 may be disposed on the device region DR and the scribe lane region SLR of the substrate 111 and cover the peripheral circuit PERI. The first insulating layer 112 may include at least one of oxide, nitride and any combination thereof.

The first interconnection structure CB1 may be disposed in the device region DR of the first insulating layer 112. The first interconnection structure CB1 may include a plurality of first interconnections ML1 and a plurality of first contacts CT1. The first contacts CT1 may connect the peripheral circuit PERI and the first interconnection ML1, and may connect the first interconnections ML1 which are disposed at different levels.

The first dummy interconnection structure DCB1 may be disposed in the scribe lane region SLR of the first insulating layer 112. The first dummy interconnection structure DCB1 may include a plurality of first dummy interconnections DML1 and a plurality of first dummy contacts DCT1.

The first interconnection ML1 and the first dummy interconnection DML1 may be formed by a metal different from the first contact CT1 and the first dummy contact DCT1. The first interconnection ML1 and the first dummy interconnection DML1 may be formed by a metal which has a slower oxidation rate than the first contact CT1 and the first dummy contact DCT1. For example, the first interconnection ML1 and the first dummy interconnection DML1 may be formed by copper (Cu), and the first contact CT1 and the first dummy contact DCT1 may be formed by tungsten (W). In order to lower interconnection resistance, copper (Cu), which has low resistivity, may be used as a material for the first interconnection ML1 and the first dummy interconnection DML. The first contact CT1 and the first dummy contact DCT1 may be created by forming contact holes, filling the contact holes with a metal material and then removing the metal material formed outside the contact holes. In order to reduce a filling defect in the process of filling the contact holes with a conductive material, tungsten (W), which has a fast oxidation rate but has excellent step coverage, may be used as a material for the first contact CT1 and the first dummy contact DCT1.

The first bonding layer 12 may be disposed on the device region DR of the first chip body 11. As described above with reference to FIG. 1, the first bonding layer 12 may include the first bonding pads P1 and the first bonding insulating layer D1. The first bonding pad P1 may be connected to the first interconnection structure CB1, and may be connected to the peripheral circuit PERI through the first interconnection structure CB1.

The second chip body 22 may include a second insulating layer 221, a stack 222, a plurality of cell plugs CP, a third insulating layer 223, a source plate 224 and a fourth insulating layer 225.

The second insulating layer 221 may be disposed on the second bonding layer 21. The second insulating layer 221 may include at least one of oxide, nitride and any combination thereof.

A second interconnection structure CB2 may be defined in the second insulating layer 221 to be connected to the second bonding pad P2. The second interconnection structure CB2 may include a second interconnection ML2 and second contacts CT2. The second interconnection ML2 may include a bit line.

The stack 222 may be disposed on the second insulating layer 221. The stack 222 may include a plurality of electrode layers 222A and a plurality of interlayer insulating layers 222B which are alternately stacked along the cell plugs CP which vertically extends. The electrode layers 222A may include a conductive material, for example, tungsten. The interlayer insulating layers 222B may include an insulating material, for example, oxide.

The electrode layers 222A may include a plurality of word lines and a plurality of select lines. Among the electrode layers 222A, at least one electrode layer 222A from a lowermost electrode layer 222A may form a first select line, and at least one electrode layer 222A from an uppermost electrode layer 222A may form a second select line. The first select line may be a drain select line, and the second select line may be a source select line. Electrode layers 222A between the first select line and the second select line may be configured as word lines. Memory cells may be formed in portions where the word lines surround the cell plugs CP. Select transistors may be formed in portions where a select line surrounds the cell plugs CP.

The cell plug CP may include, for example, a filling layer, a channel layer which surrounds the filling layer and a memory layer which surrounds the channel layer. The filling layer, the channel layer and the memory layer may vertically pass through the plurality of electrode layers 222A and the plurality of interlayer insulating layers 222B. The filling layer may include an insulating material. For example, the filling layer may include oxide. The channel layer may include a semiconductor material. For example, the channel layer may include polysilicon. The memory layer may include a tunnel insulating layer which surrounds the channel layer, a data storage layer which surrounds the tunnel insulating layer and a blocking layer which surrounds the data storage layer. The tunnel insulating layer may include a material capable of charge tunneling. For example, the tunnel insulating layer may include oxide. In an embodiment, the data storage layer may include a material capable of charge trapping. For example, the data storage layer may include nitride. In another embodiment, the data storage layer may include various materials depending on a data storage scheme. For example, the data storage layer may include silicon, a phase change material or nanodots. The blocking layer may include a material capable of blocking movement of charges. For example, the blocking layer may include oxide.

The channel layer of the cell plug CP may be connected to the second interconnection ML2 which is used as a bit line, through the second contacts CT2, and may be connected to the second bonding pad P2 through the second contact CT2 connected to the second interconnection ML2. Each of the electrode layers 222A may be connected to a second bonding pad P2 through a second interconnection structure.

The third insulating layer 223 may be provided on the second insulating layer 221 to surround the side surface of the stack 222. The third insulating layer 223 may include at least one of an oxide, a nitride and any combination thereof.

The source plate 224 may be provided on the stack 222. The source plate 224 may include, for example, polysilicon, but is not limited thereto.

The fourth insulating layer 225 may be provided on the third insulating layer 223, and may surround the side surface of the source plate 224. The fourth insulating layer 225 may include at least one of oxide, nitride and any combination thereof.

The semiconductor device may include a guard ring GD. The guard ring GD may be disposed at or near an edge of the device region DR to surround a center portion of the device region DR.

The guard ring GD may serve to block a crack likely to occur during a dicing process from propagating to the inside of the device region DR or moisture from being transferred through the crack. In addition, the guard ring GD may serve to block electromagnetic interference (EMI) and electrostatic discharge (ESD) generated outside the device region DR and discharge them to the outside again.

Although the disclosed technology illustrates a case where one guard ring GD is included, the disclosed technology is not limited thereto. Two, three or more guard rings may be defined at the edge of the device region DR to doubly, triply or more surround the device region DR.

The first bonding layer 12 and the second chip 20 may be disposed on the device region DR of the first chip body 11. The first bonding layer 12 and the second chip 20 may overlap with the device region DR of the first chip body 11, and may not overlap with the scribe lane region SLR of the first chip body 11. The side surface of the first bonding layer 12 and the side surface of the second chip 20 may be retracted inward of the side surface of the first chip body 11.

The first dummy contact DCT1 may be disposed on the top surface of the scribe lane region SLR of the first chip body 11. The first dummy contact DCT1 which is disposed on the top surface of the scribe lane region SLR of the first chip body 11 may be positioned at the same level as an uppermost first contact CT1 which is positioned uppermost among the first contacts CT1 of the first interconnection structure CB1. The uppermost first contact CT1 may be directly connected to the first bonding pad P1. The top surface of the first chip body 11 may be disposed at the same level in the device region DR and the scribe lane region SLR.

The insulating member 30 may be defined on the scribe lane region SLR of the first chip body 11 and the second chip 20 to cover the side surface of the first bonding layer 12 and the side surface and the top surface of the second chip 20.

A third contact CT3 may be formed in the device region DR of the insulating member 30. The third contact CT3 may be connected to the source plate 224 by passing through the insulating member 30.

A third dummy contact DCT3 may be formed in the scribe lane region SLR of the insulating member 30. The third dummy contact DCT3 may be disposed at the same level as the third contact CT3. The lower end of the third dummy contact DCT3 may be positioned inside the insulating member 30. A guard ring contact GCT3 may be formed in the device region DR of the insulating member 30. The guard ring contact GCT3 may be connected to the guard ring GD by passing through the insulating member 30.

A third interconnection ML3 which is connected to the third contact CT3 may be formed on the device region DR of the insulating member 30. A third dummy interconnection DML3 which is connected to the third dummy contact DCT3 may be formed on the scribe lane region SLR of the insulating member 30. A guard ring interconnection GML3 which is connected to the guard ring contact GCT3 may be formed on the device region DR of the insulating member 30.

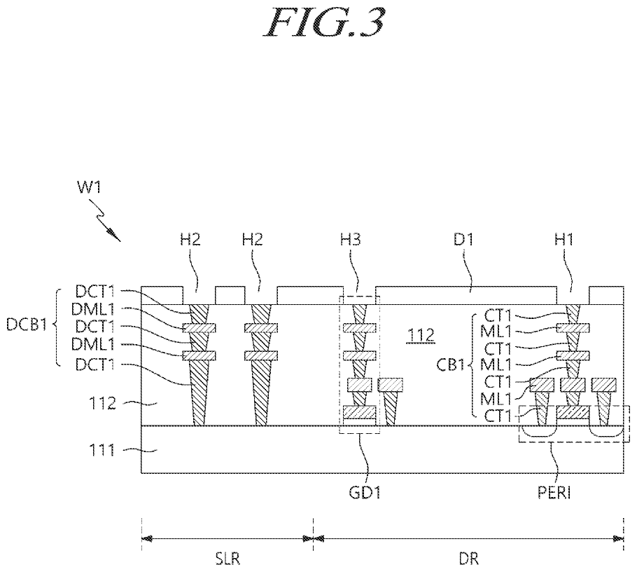

FIGS. 3 to 12 are views for explaining a method for manufacturing a semiconductor device according to an embodiment of the disclosed technology.

Referring to FIG. 3, a step of forming openings H1, H2 and H3 in a first bonding insulating layer D1 of a first wafer W1 is performed.

The first wafer W1 may include a device region DR and a scribe lane region SLR. Although FIG. 3 illustrates only one device region DR, a plurality of device regions may be two-dimensionally arranged in the first wafer W1, and the scribe lane region SLR may surround each of the device regions.

The first wafer W1 may include a substrate 111, a peripheral circuit PERI which is defined on the device region DR of the substrate 111, a first insulating layer 112 which is disposed on the substrate 111 and covers the peripheral circuit PERI, and a first interconnection structure CB1 and a first dummy interconnection structure DCB1 which are disposed in the first insulating layer 112.

The first interconnection structure CB1 may include first interconnections ML1 and first contacts CT1. The first dummy interconnection structure DCB1 may include first dummy interconnections DML1 and first dummy contacts DCT1. Additionally or optionally, a first guard ring part GD1 may be formed in the first insulating layer 112 at the edge of the device region DR. The first guard ring part GD1 may be formed together with a peripheral transistor TR and the first interconnection structure CB1 during a process of forming the peripheral transistor TR and the first interconnection structure CB1.

By forming the first bonding insulating layer D1 on the first insulating layer 112 and patterning the first bonding insulating layer D1, the openings H1, H2 and H3 may be formed.

The openings H1, H2 and H3 may include a first opening H1 which exposes the first interconnection structure CB1 and a second opening H2 which exposes the first dummy interconnection structure DCB1. Additionally or optionally, a third opening H3 which exposes the first guard ring part GD1 may be further included.

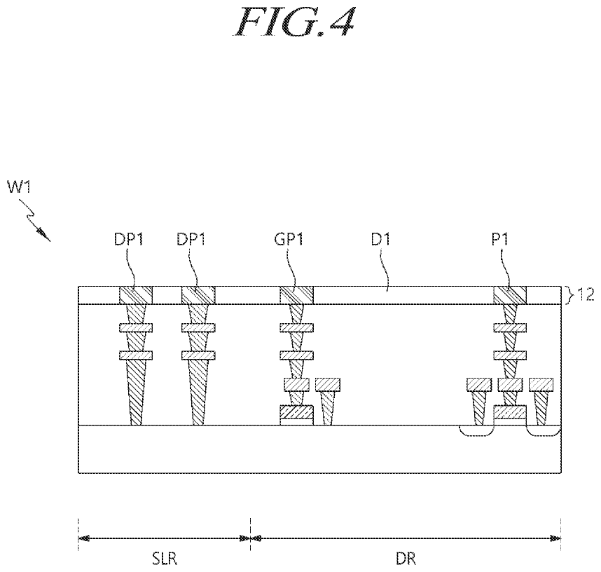

Referring to FIG. 4, a step of forming a first bonding pad P1, a first dummy bonding pad DP1 and a first guard ring pad GP1 is performed.

A metal material may be formed on the first insulating layer 112 and the first bonding insulating layer D1 to fill the first to third openings H1 to H3 and removing the metal material formed outside the first to third openings H1 to H3 by a CMP process, the first bonding pad P1 may be formed in the first opening H1, the first dummy bonding pad DP1 may be formed in the second opening H2, and the first guard ring pad GP1 may be formed in the third opening H3. Accordingly, a first bonding layer 12 including the first bonding pad P1, the first dummy bonding pad DP1, the first guard ring pad GP1 and the first bonding insulating layer D1 may be formed on the top surface of the first wafer W1.

The metal material may include, for example, at least one of copper (Cu), tungsten (W), cobalt (Co), aluminum (Al), silicide and any combination thereof. The metal material may be formed through a plating process, but is not limited thereto.

By forming the first dummy bonding pad DP1 in the scribe lane region SLR and the first bonding pad P1 in the device region DR, a difference in pattern density between the device region DR and the scribe lane region SLR may be reduced. Therefore, it is possible to suppress or/and prevent occurrence of dishing and erosion in a CMP process due to the difference in pattern density.

Although the disclosed technology illustrates that the first dummy bonding pad DP1 is formed only in the scribe lane region SLR, a first dummy bonding pad may also be formed in the device region DR.

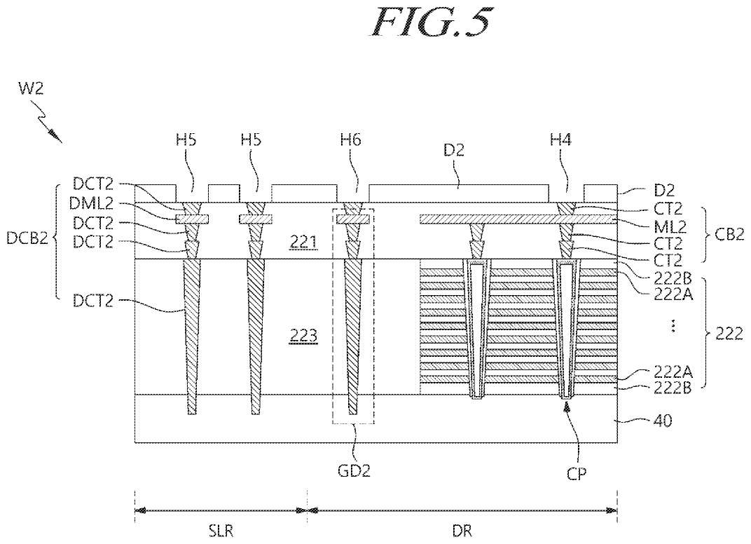

Referring to FIG. 5, a step of forming openings H4, H5 and H6 in a second bonding insulating layer D2 of a second wafer W2 is performed.

The second wafer W2 may include a device region DR and a scribe lane region SLR. Although FIG. 5 illustrates only one device region, a plurality of device regions may be two-dimensionally arranged in the second wafer W2, and the scribe lane region SLR may surround each of the device regions.

The second wafer W2 may include a stack 222, a plurality of cell plugs CP, second and third insulating layers 221 and 223, a second interconnection structure CB2 and a second dummy interconnection structure DCB2 which are disposed on a support structure 40.

The stack 222 and the cell plugs CP may be disposed on the device region DR of the support structure 40. The third insulating layer 223 may be disposed on the device region DR and the scribe lane region SLR of the support structure 40 to cover the side surface of the stack 222. The second insulating layer 221 may be disposed on the stack 222 and the third insulating layer 223 to cover the top surface of the stack 222 and the top surface of the third insulating layer 223.

The second interconnection structure CB2 may be disposed in the device region DR of the second insulating layer 221, and may include a second interconnection ML2 and second contacts CT2. The second dummy interconnection structure DCB2 may be disposed in the scribe lane region SLR of the second insulating layer 221 and the third insulating layer 223, and may include a second dummy interconnection DML2 and second dummy contacts DCT2.

Additionally or optionally, a second guard ring part GD2 which passes through the second insulating layer 221 and the third insulating layer 223 may be formed at the edge of the device region DR. The second guard ring part GD2 may be created together with the second dummy interconnection DML2 and the second dummy contacts DCT2 in the process of forming the second dummy interconnection DML2 and the second dummy contacts DCT2.

By forming the second bonding insulating layer D2 on the second insulating layer 221 and patterning the second bonding insulating layer D2, the openings H4, H5 and H6 may be formed.

The openings H4, H5 and H6 may include a fourth opening H4 which exposes the second interconnection structure CB2, a fifth opening H5 which exposes the second dummy interconnection structure DCB2 and a sixth opening H6 which exposes the second guard ring part GD2.

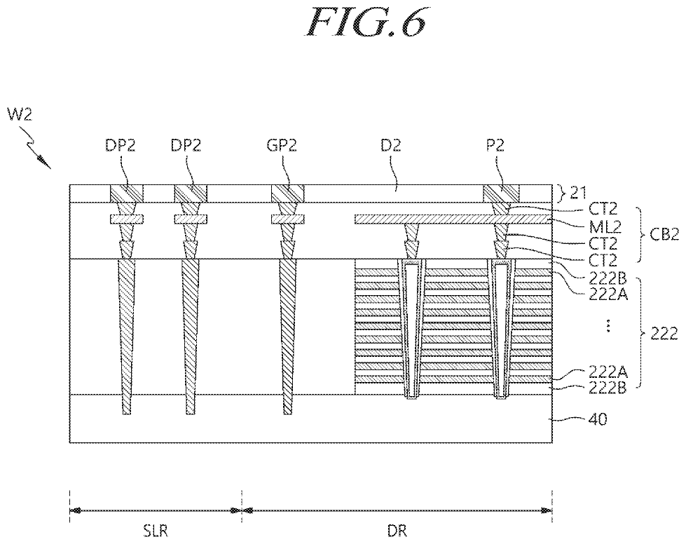

Referring to FIG. 6, a step of forming a second bonding pad P2 and a second dummy bonding pad DP2 is performed.

A metal material may be formed on the second insulating layer 221 and the second bonding insulating layer D2 to fill the fourth to sixth openings H4 to H6, and the metal material formed outside the fourth to sixth openings H4 to H6 may be removed through a CMP process. Accordingly, the second bonding pad P2 may be formed in the fourth opening H4, the second dummy bonding pad DP2 may be formed in the fifth opening H5, and a second guard ring pad GP2 may be formed in the sixth opening H6. By this fact, a second bonding layer 21 including the second bonding pad P2, the second dummy bonding pad DP2, the second guard ring pad GP2 and the second bonding insulating layer D2 may be formed on the top surface of the second wafer W2.

The metal material may include, for example, at least one of copper (Cu), tungsten (W), cobalt (Co), aluminum (Al), silicide and any combination thereof. The metal material may be formed through a plating process, but is not limited thereto.

By forming the second dummy bonding pad DP2 in the scribe lane region SLR and the second bonding pad P2 in the device region DR, a difference in pattern density between the device region DR and the scribe lane region SLR may be reduced. Therefore, it is possible to suppress or/and prevent occurrence of dishing and erosion in a CMP process due to the difference in pattern density.

Although the disclosed technology illustrates that the second dummy bonding pad DP2 is formed only in the scribe lane region SLR, a second dummy bonding pad may also be formed in the device region DR.

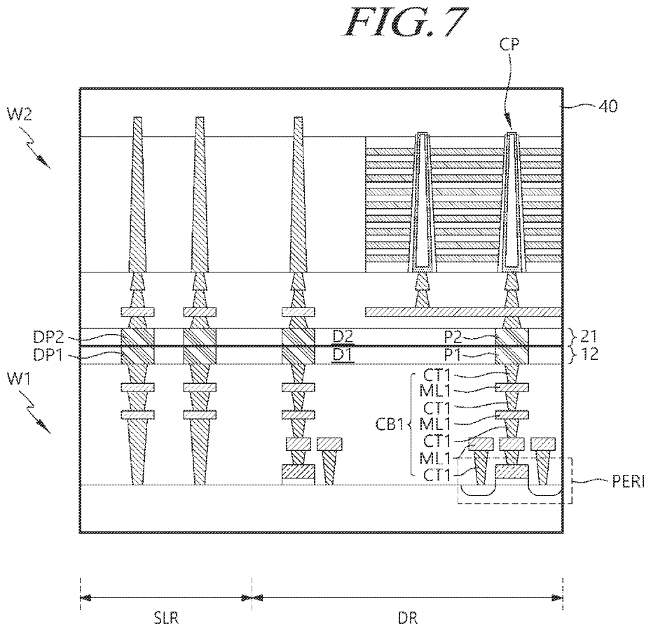

Referring to FIG. 7, a wafer bonding step of bonding the first wafer W1 and the second wafer W2 is performed.

The wafer bonding step may include turning the second wafer W2 upside down, and bonding the first bonding layer 12 of the first wafer W1 and the second bonding layer 21 of the second wafer W2 through a hybrid bonding process.

While performing the hybrid bonding process, the first bonding insulating layer D1 and the second bonding insulating layer D2 may be first bonded. The first bonding pad P1 and the second bonding pad P2 may be bonded as the metal materials in the first and second bonding pads P1 and P2 expand by subsequently applied heat. As the first bonding pad P1 and the second bonding pad P2 are bonded, the peripheral circuit PERI and a memory cell array may be electrically connected.

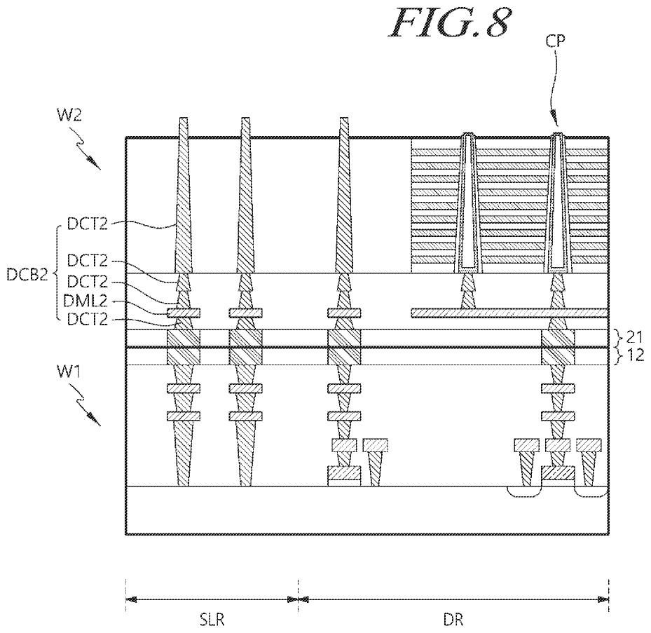

Referring to FIG. 8, a step of removing the support structure 40 is performed.

The support structure 40 may be removed using an etching material capable of selectively etching the support structure 40. As the support structure 40 is removed, the cell plug CP and the second dummy interconnection structure DCB2 may be exposed on the top surface of the second wafer W2.

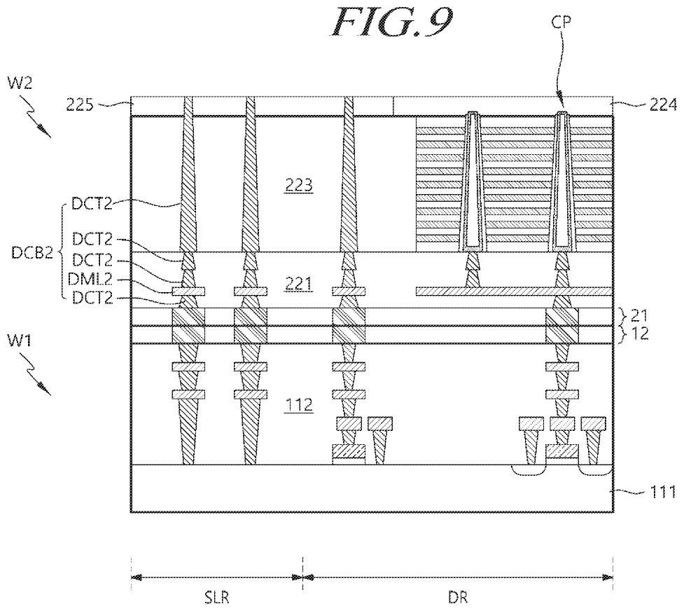

Referring to FIG. 9, a step of forming a source plate 224 and a fourth insulating layer 225 is performed.

After forming the source plate 224, connected to the cell plug CP, on the stack 222 and forming the fourth insulating layer 225 on the third insulating layer 223 and the source plate 224, the fourth insulating layer 225 may be planarized to expose the second dummy interconnection structure DCB2 and the source plate 224.

Referring to FIG. 10, a step of removing the second wafer W2 and the first bonding layer 12 of the scribe lane region SLR is performed.

By forming a mask pattern on the source plate 224, the scribe lane region SLR on the second wafer W2 may be exposed. The second wafer W2 and the first bonding layer 12 may be etched using the mask pattern as an etch mask, and a trench TH may be formed. The trench TH may be formed to expose an uppermost first dummy contact DCT1 of the first dummy interconnection structure DCB1.

During the etching process, the first and second bonding layers 12 and 21 of the scribe lane region SLR may be removed.

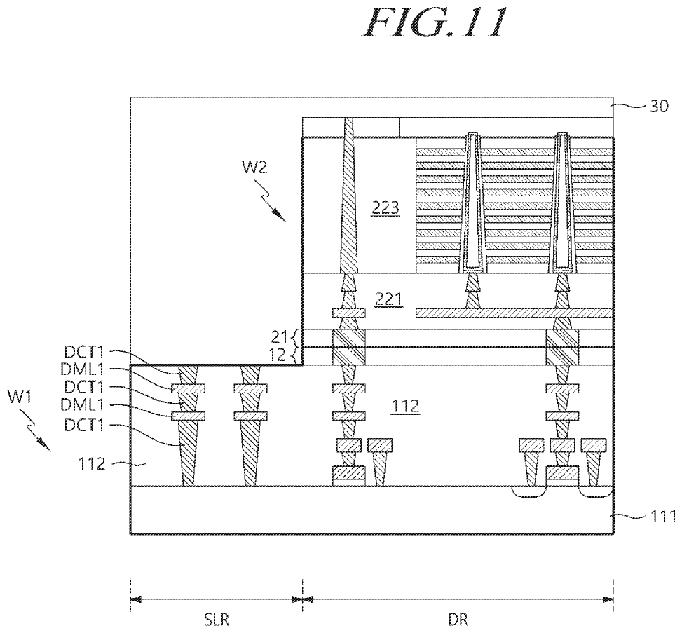

Referring to FIG. 11, a step of forming an insulating member 30 is performed.

By forming the insulating member 30 on the first and second wafers W1 and W2, the trench TH may be filled. The insulating member 30 may include an insulating material with a modulus of rupture smaller than that of the first and second bonding pads P1 and P2. For example, the insulating member 30 may include at least one of oxide, nitride, SiCOH, N-doped SiC (NDC) and any combination thereof.

Then, the top surface of the insulating member 30 may be planarized through a CMP process.

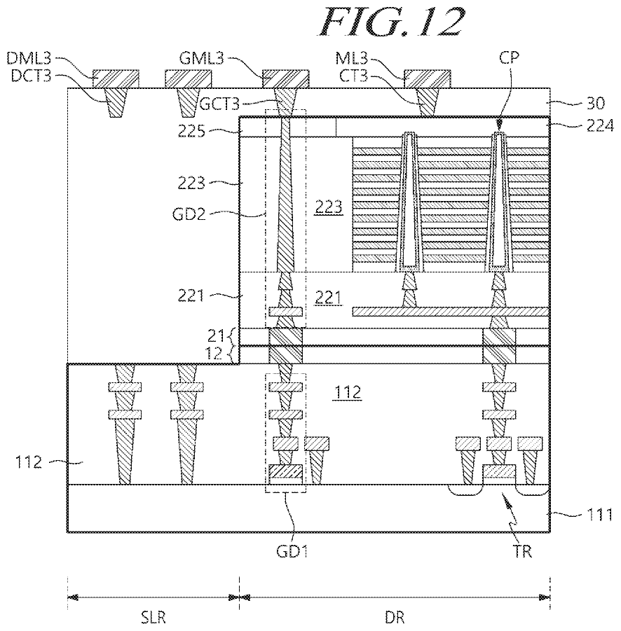

Referring to FIG. 12, a step of forming a third contact CT3 and a third interconnection ML3 is performed.

By forming a contact hole which exposes the source plate 224, in the device region DR of the insulating member 30 through a photolithography process and filling a conductive material in the contact hole, the third contact CT3 may be formed. In the process of forming the third contact CT3, a third dummy contact DCT3 may be formed in the scribe lane region SLR. Additionally or optionally, in the process of forming the third contact CT3 and the third dummy contact DCT3, a guard ring contact GCT3 which is connected to the second guard ring part GD2 may be formed.

A third interconnection ML3 which is connected to the third contact CT3 may be formed on the device region DR of the insulating member 30. In the process of forming the third interconnection ML3, a third dummy interconnection DML3 may be formed in the scribe lane region SLR. Additionally or optionally, in the process of forming the third interconnection ML3 and the third dummy interconnection DML3, a guard ring interconnection GML3 which is connected to the guard ring contact GCT3 may be formed.

Thereafter, a step of cutting the scribe lane region SLR through a dicing process may be performed. During the dicing process, the insulating member 30, the first insulating layer 112 and the substrate 111 of the scribe lane region SLR may be cut.

The first and second dummy bonding pads DP1 and DP2 of the scribe lane region SLR serve to prevent dishing and erosion during the process of forming the first and second bonding pads P1 and P2, but may serve as a source of delamination.

In detail, a metal material comprising the first and second dummy bonding pads DP1 and DP2 has a large modulus of rupture. This characteristic may result in poor cuttability, and an abnormal profile. For example, a step-shaped surface may be created on the surface after the dicing process. As a stress is concentrated on the abnormal profile created on the surface that is cut, the first and second chips (10 and 20 of FIG. 2) may be delaminated in a subsequent process such as a molding process. As metal ions included in the first and second bonding pads P1 and P2 migrate along a delaminated surface, bonding pads which should not be connected to each other may be short-circuited, thereby degrading the reliability of a semiconductor device.

According to the embodiment of the disclosed technology, since the cuttability of the scribe lane region SLR may be increased by removing the first and second dummy bonding pads DP1 and DP2 of the scribe lane region SLR after wafer bonding, it is possible to suppress or/and prevent an abnormal profile from being created on a surface that is cut during a dicing process. Therefore, by preventing delamination of bonded chips and preventing a migration phenomenon accompanying delamination, the reliability of a semiconductor device may be improved.

FIG. 13 is a schematic cross-sectional view of a semiconductor device according to an embodiment of the disclosed technology.

Referring to FIG. 13, the top surface of a scribe lane region SLR of a first chip body 11 may be disposed to be lower than the top surface of a device region DR of the first chip body 11.

During an etching process for removing a second chip 20 and a first bonding layer 12 of the scribe lane region SLR, the first chip body 11 of the scribe lane region SLR may be partially etched. As a result of the etching process, an inner side surface SS1b may be created on the first chip body 11. The inner side surface SS1b of the first chip body 11 may be disposed on the same surface as a side surface SS2 of the first bonding layer 12 and a side surface SS3 of the second chip 20.

FIG. 14 is a detailed view of a part B of FIG. 13.

Referring to FIG. 14, the top surface of the scribe lane region SLR of the first chip body 11 may be positioned to be lower than the top surface of the device region DR of the first chip body 11. A first dummy interconnection DML1 may be positioned on the top surface of the scribe lane region SLR of the first chip body 11.

As described above, a first interconnection ML1 and the first dummy interconnection DML1 may be formed of copper, and a first contact CT1 and a first dummy contact DCT1 may be formed of tungsten. Since tungsten has a faster oxidation rate than copper and is thus easily oxidated, an uppermost first dummy contact DCT1 may be easily oxidated during an etching process for forming the trench (TH of FIG. 10) described above with reference to FIG. 10. Thus, by removing the uppermost first dummy contact DCT1, the first dummy interconnection DML1 under the uppermost first dummy contact DCT1 may be exposed. To this end, by controlling the etching process for forming the trench (TH of FIG. 10) so that etching is stopped at the first dummy interconnection DML1, the scribe lane region SLR of the first chip body 11 may be partially etched. In this case, the top surface of the scribe lane region SLR of the first chip body 11 may be disposed at the same level as the top surface of the first dummy interconnection DML1.

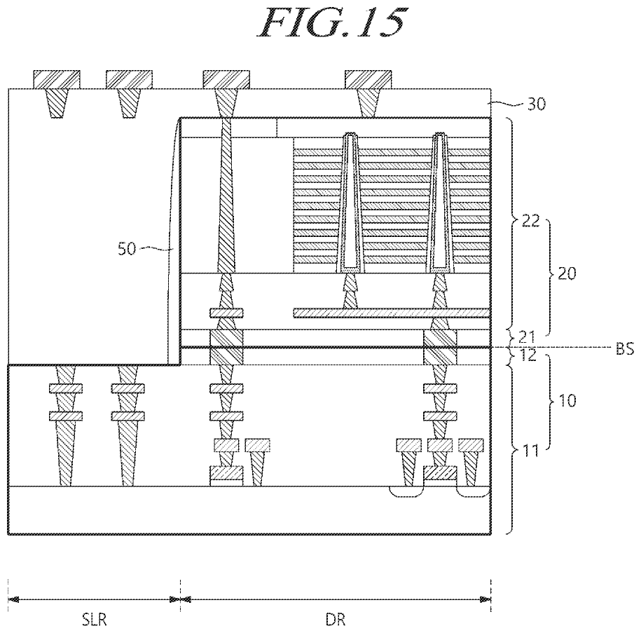

FIG. 15 is a cross-sectional view illustrating a part of a semiconductor device according to an embodiment of the disclosed technology.

Referring to FIG. 15, a moisture penetration prevention member 50 may be configured between a first bonding layer 12 and an insulating member 30 and between the side surface of a second chip 20 and the insulating member 30. The moisture penetration prevention member 50 may include nitride. After forming a trench (TH of FIG. 10) and before forming the insulating member 30, the moisture penetration prevention member 50 may be formed on the side surfaces of the first bonding layer 12 and the second chip 20 which are exposed by the trench (TH of FIG. 10).

The moisture penetration prevention member 50 may surround the side surfaces of the first bonding layer 12 and the second chip 20. Although not illustrated in detail in a drawing, edge of a bonding interface BS between a first chip 10 and the second chip 20 may be surrounded by the moisture penetration prevention member 50 and blocked from the outside. Accordingly, penetration of moisture into the bonding interface BS may be suppressed or/and prevented. When moisture penetrates into the bonding interface BS and heat is applied to the bonding interface BS, first and second bonding pads P1 and P2 are likely to be oxidated. Since the bonding interface BS is blocked from the outside by the moisture penetration prevention member 50 to suppress or/and prevent moisture from penetrating into the bonding interface BS, it is possible to provide a semiconductor device with high reliability.

Although embodiments of the present disclosure have been described for illustrative purposes, those skilled in the art will appreciate that various modifications, additions and substitutions are possible, without departing from the scope of the present disclosure. Therefore, the embodiments disclosed above and in the accompanying drawings should be considered in a descriptive sense only and not for limiting the technological scope. The technological scope of the present disclosure is not limited by the embodiments and the accompanying drawings.

What is claimed is:

1. A semiconductor device comprising:
a first chip including a first chip body and a first bonding layer disposed on the first chip body, the first bonding layer including a first bonding pad; and
a second chip bonded on the first bonding layer, the second chip including a second chip body and a second bonding layer disposed under the second chip body,
wherein the second bonding layer includes a second bonding pad bonded to the first bonding pad,
wherein a side surface of the first bonding layer and a side surface of the second chip are retracted inward of a side surface of the first chip body.

2. The semiconductor device according to claim 1, further comprising:
an insulating member disposed on an edge portion of the first chip body which protrudes beyond the side surface of the first bonding layer and the side surface of the second chip.

3. The semiconductor device according to claim 2, wherein the insulating member comprises an insulating material with a modulus of rupture smaller than that of the first and second bonding pads.

4. The semiconductor device according to claim 2, wherein the insulating member comprises at least one of oxide, nitride, SiCOH, N-doped SiC (NDC) and any combination thereof.

5. The semiconductor device according to claim 2, further comprising:
a moisture penetration prevention member disposed between the side surface of the first bonding layer and the insulating member and between the side surface of the second chip and the insulating member.

6. The semiconductor device according to claim 5, wherein the moisture penetration prevention member comprises nitride.

7. The semiconductor device according to claim 1, wherein a top surface of the edge portion of the first chip body which protrudes beyond the side surface of the first bonding layer and the side surface of the second chip is disposed to be lower than a top surface of a center portion of the first chip body which overlaps with the first bonding layer and the second chip.

8. A semiconductor device comprising:
a first chip including a first chip body including a device region in which a peripheral circuit is defined and a scribe lane region which surrounds the device region, and a first bonding layer disposed on the first chip body and including a first bonding pad; and
a second chip bonded on the first bonding layer, and including a second bonding layer including a second bonding pad which is bonded to the first bonding pad and a second chip body disposed on the second bonding layer and including a memory cell array,
wherein the first bonding layer and the second chip overlap with the device region of the first chip body, and do not overlap with the scribe lane region of the first chip body.

9. The semiconductor device according to claim 8, further comprising:
an insulating member disposed on the scribe lane region of the first chip body and the second chip, and covering a side surface of the first bonding layer and a top surface and a side surface of the second chip.

10. The semiconductor device according to claim 8, wherein the first chip body comprises:
a substrate;
the peripheral circuit disposed on the substrate;
a first insulating layer disposed on the substrate, and covering the peripheral circuit;
a contact disposed in the device region of the first insulating layer, and directly connected to the first bonding pad; and
a dummy contact disposed in the scribe lane region of the first insulating layer, and positioned at the same level as the contact,
wherein a top surface of the scribe lane region of the first chip body is disposed at the same level as a top surface of the dummy contact.

11. The semiconductor device according to claim 8, wherein the first chip body comprises:
a substrate;
the peripheral circuit disposed on the substrate;
a first insulating layer covering the peripheral circuit;
an interconnection disposed in the device region of the first insulating layer; and
a dummy interconnection disposed in the scribe lane region of the first insulating layer, and positioned at the same level as the interconnection,
wherein a top surface of the scribe lane region of the first chip body is disposed at the same level as a top surface of the dummy interconnection.

12. The semiconductor device according to claim 8, wherein the second chip body comprises:
a first insulating layer disposed on the second bonding layer;
a stack disposed on the first insulating layer, and including a plurality of interlayer insulating layers and a plurality of electrode layers alternately stacked along a cell plug which extends in a vertical direction;
a second insulating layer disposed on the first insulating layer, and surrounding a side surface of the stack;
a source plate disposed on the stack; and
a third insulating layer disposed on the second insulating layer, and surrounding a side surface of the source plate.

13. The semiconductor device according to claim 12, further comprising:
a contact connected to the source plate by passing through the insulating member in the device region;
a top interconnection disposed on the insulating member, and connected to the contact;
a dummy contact passing through a top surface of the insulating member in the scribe lane region, and disposed at the same level as the contact; and
a dummy top interconnection disposed on the insulating member, and connected to the dummy contact.

14. A method for manufacturing a semiconductor device, comprising:
providing first and second wafers including a device region and a scribe lane region surrounding the device region;
forming, in each of the first and second wafers, a bonding layer and a chip body disposed on the bonding layer, the bonding layer including a bonding pad which is disposed in the device region and a dummy bonding pad which is disposed in the scribe lane region;
bonding a first bonding layer of the first wafer and a second bonding layer of the second wafer;
forming a trench by removing a second chip of the second wafer and the first bonding layer of the scribe lane region;
forming an insulating member which fills the trench; and
cutting the scribe lane region.

15. The method according to claim 14, wherein the forming of a bonding layer comprises:
forming, on one surface of each of the first and second wafers, a bonding insulating layer having a first opening which exposes the device region and a second opening which exposes the scribe lane region;
forming a metal material which fills the first and second openings; and
forming the bonding pad in the first opening and forming the dummy bonding pad in the second opening by removing the metal material formed outside the first and second openings.

16. The method according to claim 14, wherein the insulating member comprises an insulating material with a modulus of rupture smaller than that of the bonding pad and the dummy bonding pad.

17. The method according to claim 14, wherein
the first wafer includes a contact which is disposed in the device region and is directly connected to the bonding pad of the first wafer, and a dummy contact which is disposed in the scribe lane region and is positioned at the same level as the contact, and
the trench is formed to expose the dummy contact.

18. The method according to claim 14, wherein
the first wafer further includes an interconnection which is disposed in the device region, and a dummy interconnection which is disposed in the scribe lane region and is positioned at the same level as the interconnection, and
the trench is formed to expose the dummy interconnection.

19. The method according to claim 14, further comprising:
forming a moisture penetration prevention member on a sidewall of the trench before forming the insulating member.
